(19) United States
(12) Patent Application Publication
(10) Pub. No.: US 2025/0203785 A1
(43) Pub. Date: Jun. 19, 2025

(54) CIRCUIT BOARD STRUCTURE AND MANUFACTURING METHOD THEREOF

(71) Applicant: TONG HSING ELECTRONIC INDUSTRIES, LTD., Taipei City (TW)

(72) Inventors: CHUNG-HO WEI, Taipei City (TW); CHIH-WEI MAO, Taipei City (TW); Yi-Lun Chu, Taipei City (TW); TSUNG-YING CHANG, Taipei City (TW); MING-YI HSU, Taipei City (TW); CHI-WEN HUANG, Taipei City (TW)

(21) Appl. No.: 18/610,205

(22) Filed: Mar. 19, 2024

(30) Foreign Application Priority Data
Dec. 15, 2023 (TW) 112148955

(51) Int. Cl. H05K 3/42; H05K 1/03; H05K 3/46

(52) U.S. Cl. CPC H05K 3/423; H05K 1/0306; H05K 3/4629

(57) ABSTRACT

A circuit board structure and a manufacturing method thereof are provided. The circuit board structure includes a ceramic board, a thick circuit layer formed on the ceramic board, and a thin circuit layer that is formed on the ceramic board. The thick circuit layer has a thickness being greater than or equal to 200 μm, and the thin circuit layer has a thickness being within a range from 1 μm to 150 μm. The thin circuit layer includes a sputtering layout segment connected to the ceramic board and an electroplating layer that is connected to the sputtering layout segment. The material of the electroplating layer is different from that of the sputtering layout segment.

### CROSS-REFERENCE TO RELATED PATENT APPLICATION

This application claims the benefit of priority to Taiwan Patent Application No. 112148955, filed on Dec. 15, 2023. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a circuit board, and more particularly to a circuit board structure and a manufacturing method thereof.

### BACKGROUND OF THE DISCLOSURE

A conventional ceramic circuit board is formed with metal circuits by using a chemical etching process. However, since widths of the metal circuits are affected by lateral etching in the chemical etching process, the metal circuits cannot have a high accuracy of pattern and can easily have an electrical short issue. Moreover, the conventional ceramic circuit board needs to have metal circuits of different thicknesses for meeting various practical requirements.

### SUMMARY OF THE DISCLOSURE

In response to the above-referenced technical inadequacies, the present disclosure provides a circuit board structure and a manufacturing method thereof for effectively improving on the issues associated with conventional ceramic circuit boards.

In order to solve the above-mentioned problems, one of the technical aspects adopted by the present disclosure is to provide a manufacturing method of a circuit board structure, which includes a preparing step, a patterning step, a sputtering step, a shielding step, an electroplating step, and a chemical etching step. The preparing step is implemented by providing a metallized ceramic substrate. The metallized ceramic substrate includes a ceramic board, a first metal layer, and a second metal layer. The ceramic board has a first surface and a second surface that is opposite to the first surface. The first metal layer and the second metal layer are respectively formed on the first surface and the second surface of the ceramic board. The patterning step is implemented by patterning the first metal layer to remove a part of the first metal layer so as to form a first thick circuit layer. Moreover, a thickness of the first thick circuit layer is greater than or equal to 200 μm, and a part of the first surface is exposed from the first thick circuit layer and is defined as a first processing region. The sputtering step is implemented by sputtering the first processing region of the ceramic board to form a first sputtering conductor layer. The shielding step is implemented by forming a first shielding layer onto the first sputtering conductor layer. The first shielding layer has a first patterned trench, and a part of the first sputtering conductor layer is exposed from the first shielding layer through the first patterned trench and is defined as a first sputtering layout segment. The electroplating step is implemented by electroplating the first sputtering layout segment of the first sputtering conductor layer to form a first electroplating layer that is connected to the first sputtering layout segment. The chemical etching step is implemented by removing the first shielding layer and another part of the first sputtering conductor layer connected to the first shielding layer so as to preserve the first electroplating layer and the first sputtering layout segment that are jointly defined as a first thin circuit layer. Moreover, a thickness of the first thin circuit layer is within a range from 1 μm to 150 μm.

In order to solve the above-mentioned problems, another one of the technical aspects adopted by the present disclosure is to provide a circuit board structure, which includes a ceramic board, a thick circuit layer, and a thin circuit layer. The ceramic board has a first surface and a second surface that is opposite to the first surface. The thick circuit layer is formed on the first surface of the ceramic board and has a thickness that is greater than or equal to 200 μm. Moreover, a part of the first surface is exposed from the first thick circuit layer and is defined as a first processing region. The thin circuit layer is formed on the first processing region of the first surface and has a thickness that is within a range from 1 μm to 150 μm. The thin circuit layer includes a sputtering layout segment connected to the first surface and a first electroplating layer that is connected to the sputtering layout segment, and the first electroplating layer and the first sputtering layout segment are respectively made of different materials.

In order to solve the above-mentioned problems, yet another one of the technical aspects adopted by the present disclosure is to provide a circuit board structure, which includes a ceramic board, a thick circuit layer, and a sputtering circuit layer. The ceramic board having a first surface and a second surface that is opposite to the first surface. The thick circuit layer is formed on the first surface of the ceramic board and has a thickness that is greater than or equal to 200 μm. Moreover, a part of the first surface is exposed from the first thick circuit layer and is defined as a first processing region. The sputtering circuit layer is formed on the first processing region of the first surface and has a thickness that is within a range from 0.1 μm to 1 μm.

Therefore, any one of the manufacturing method and the circuit board structure provided by the present disclosure only has a slight lateral etching on the first sputtering layout segment (or the sputtering circuit layer) through the steps and configuration thereof, so that the pattern accuracy of the first thin circuit layer (or the sputtering circuit layer) is not affected for preventing an electrical short from occurring at the first thin circuit layer (or the sputtering circuit layer). Accordingly, the first thick circuit layer and the first thin circuit layer (or the sputtering circuit layer) can be accurately formed by implementing the above steps for meeting various practical requirements.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flow chart of a manufacturing method of a circuit board structure according to a first embodiment of the present disclosure;

FIG. 2 is schematic view showing a preparing step of FIG. 1;

FIG. 3 is schematic view showing a patterning step of FIG. 1;

FIG. 4 is schematic view showing a sputtering step of FIG. 1;

FIG. 5 is schematic view showing a shielding step of FIG. 1;

FIG. 6 is schematic view showing an electroplating step of FIG. 1;

FIG. 7 is schematic view showing a chemical etching step of FIG. 1;

FIG. 8 is a schematic view showing a first variation of the circuit board structure according to the first embodiment of the present disclosure;

FIG. 9 is a schematic view showing a second variation of the circuit board structure according to the first embodiment of the present disclosure;

FIG. 10 is a schematic view showing a third variation of the circuit board structure according to the first embodiment of the present disclosure;

FIG. 11 is a schematic view showing the circuit board structure according to a second embodiment of the present disclosure;

FIG. 12 is a schematic view showing the shielding step of the manufacturing method according to a third embodiment of the present disclosure;

FIG. 13 is a schematic view showing the electroplating step of the manufacturing method according to the third embodiment of the present disclosure;

FIG. 14 is a schematic view showing the chemical etching step of the manufacturing method according to the third embodiment of the present disclosure; and

FIG. 15 is a schematic view of the circuit board structure according to a fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

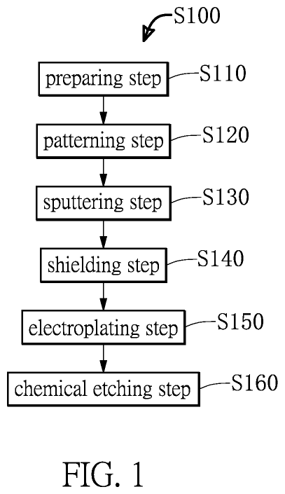

Referring to FIG. 1 to FIG. 10, a first embodiment of the present disclosure is provided. As shown in FIG. 1 to FIG. 7, the present embodiment provides a manufacturing method S100 of a circuit board structure, which sequentially includes (or implements) a preparing step S110, a patterning step S120, a sputtering step S130, a shielding step S140, an electroplating step S150, and a chemical etching step S160.

The following description sequentially describes the steps S110-S160 of the manufacturing method S100, which are implemented to manufacture a circuit board structure 100, but the present disclosure is not limited thereto. For example, in other embodiments of the present disclosure not shown in the drawings, the steps S110-S160 of the manufacturing method S100 can be adjusted (e.g., reordered, added, or canceled) according to design requirements.

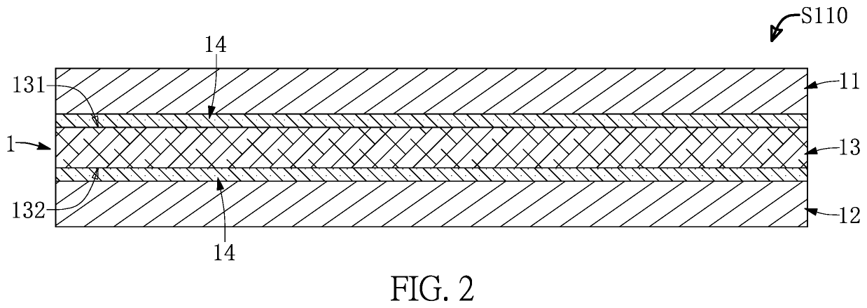

As shown in FIG. 1 and FIG. 2, the preparing step S110 is implemented by providing a metallized ceramic substrate 1, which includes a ceramic board 13, a first metal layer 11, and a second metal layer 12, the latter two of which are formed on two opposite sides of the ceramic board 13. In other words, the ceramic board 13 has a first surface 131 and a second surface 132 that is opposite to the first surface 131, and the first metal layer 11 and the second metal layer 12 are respectively formed on the first surface 131 and the second surface 132.

It should be noted that, in the preparing step S110, the metallized ceramic substrate 1 can be a direct bonded copper (DBC) ceramic substrate, and the first metal layer 11 and the second metal layer 12 are respectively sintered onto the first surface 131 and the second surface 132 of the ceramic board 13. In other words, each of the first metal layer 11 and the second metal layer 12 in the present embodiment is sintered and fixed onto the ceramic board 13 through a connection layer 14 (e.g., a sintered layer).

Or, in the preparing step S110, the metallized ceramic substrate 1 can be an active metal brazing (AMB) ceramic substrate, and the first metal layer 11 and the second metal layer 12 are respectively brazed onto the first surface 131 and the second surface 132 of the ceramic board 13. In other words, each of the first metal layer 11 and the second metal layer 12 in the present embodiment is brazed and fixed onto the ceramic board 13 through a connection layer 14 (e.g., a brazed layer).

As shown in FIG. 1 to FIG. 3, the patterning step S120 is implemented by patterning the first metal layer 11 and the second metal layer 12 to remove a part of the first metal layer 11 and a part of the second metal layer 12 so as to respectively form a first thick circuit layer 111 and a second thick circuit layer 121, and the first thick circuit layer 111 and the second thick circuit layer 121 can have different patterns or thicknesses, but the present disclosure is not limited thereto. For example, in other embodiments of the present disclosure not shown in the drawings, the manufacturing method S100 can be implemented without the patterning of the second metal layer 12 according to design requirements (e.g., an initial structure of the second metal layer 12 can be maintained, and the second thick circuit layer 121 is not formed).

Specifically, the patterning of the first metal layer 11 and the second metal layer 12 can be implemented in a film attachment manner, an exposure manner, and a development manner, and the present disclosure is not limited thereto. Moreover, each of a thickness of the first thick circuit layer 111 and a thickness of the second thick circuit layer 121 is greater than or equal to 200 μm, a part of the first surface 131 is exposed from the first thick circuit layer 111 and is defined as a first processing region 1311, and a part of the second surface 132 is exposed from the second thick circuit layer 121 and is defined as a second processing region 1321.

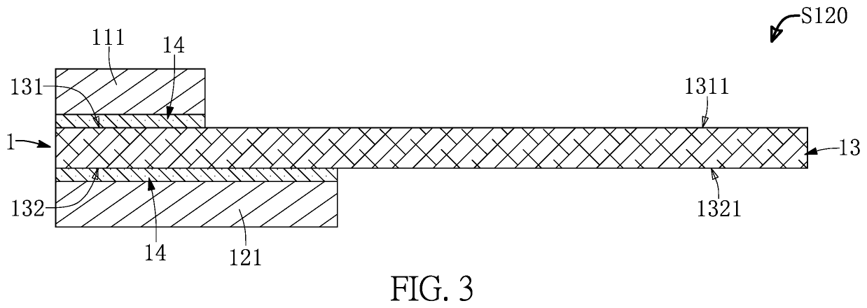

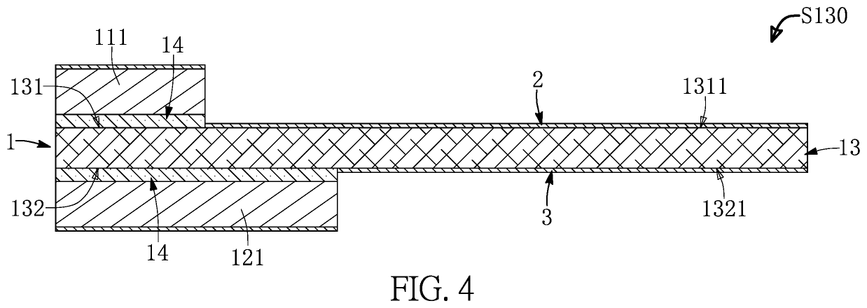

As shown in FIG. 1, FIG. 3, and FIG. 4, the sputtering step S130 is implemented by sputtering the first processing region 1311 of the ceramic board 13 to form a first sputtering conductor layer 2 and by sputtering the second processing region 1321 of the ceramic board 13 to form a second sputtering conductor layer 3, but the present disclosure is not limited thereto. For example, in other embodiments of the present disclosure not shown in the drawings, when the second metal layer 12 in the patterning step S120 is not patterned, the manufacturing method S100 is implemented without the forming of the second processing region 1321 and the second sputtering conductor layer 3.

Specifically, the first sputtering conductor layer 2 and the second sputtering conductor layer 3 are made of a same material, and each of a thickness of the first sputtering conductor layer 2 and a thickness of the second sputtering conductor layer 3 is within a range from 0.1 μm to 1 μm.

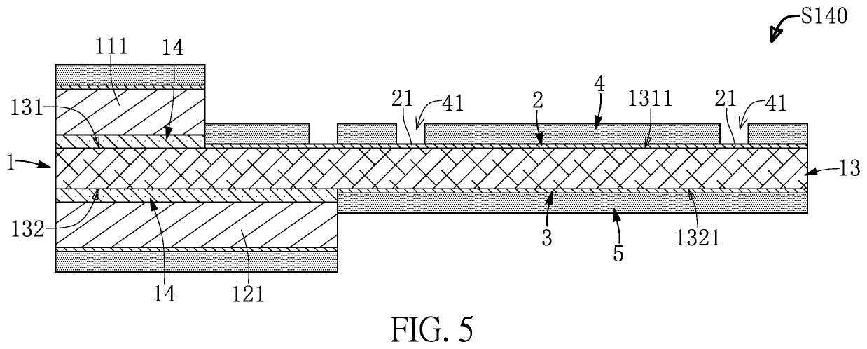

As shown in FIG. 1, FIG. 4, and FIG. 5, the shielding step S140 is implemented by forming a first shielding layer 4 onto the first sputtering conductor layer 2 and by forming a second shielding layer 5 onto the second sputtering conductor layer 3. Specifically, the first shielding layer 4 has a first patterned trench 41, and a part of the first sputtering conductor layer 2 is exposed from the first shielding layer 4 through the first patterned trench 41 and is defined as a first sputtering layout segment 21, but the present disclosure is not limited thereto.

For example, in other embodiments of the present disclosure not shown in the drawings, when the second metal layer 12 is not patterned, the manufacturing method S100 is implemented without the forming of the second shielding layer 5 for covering the second sputtering conductor layer 3 according to design requirements.

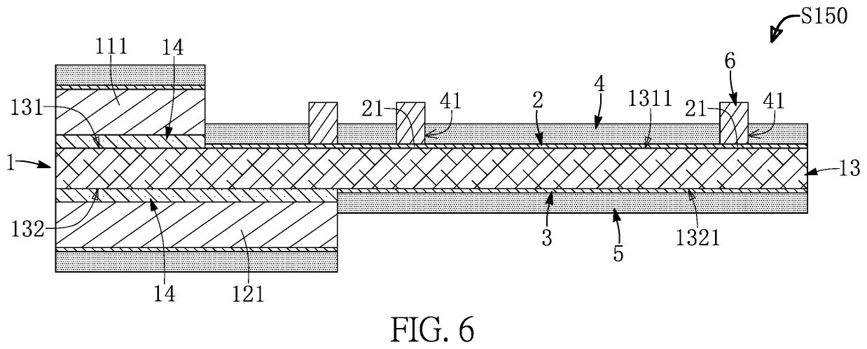

As shown in FIG. 1, FIG. 5, and FIG. 6, the electroplating step S150 is implemented by electroplating the first sputtering layout segment 21 of the first sputtering conductor layer 2 to form a first electroplating layer 6 that is connected to the first sputtering layout segment 21. In the present embodiment, the first electroplating layer 6 and the first sputtering layout segment 21 are respectively made of different materials, such that the first electroplating layer 6 in the following chemical etching step S160 does not have any lateral etching, but the present disclosure is not limited thereto.

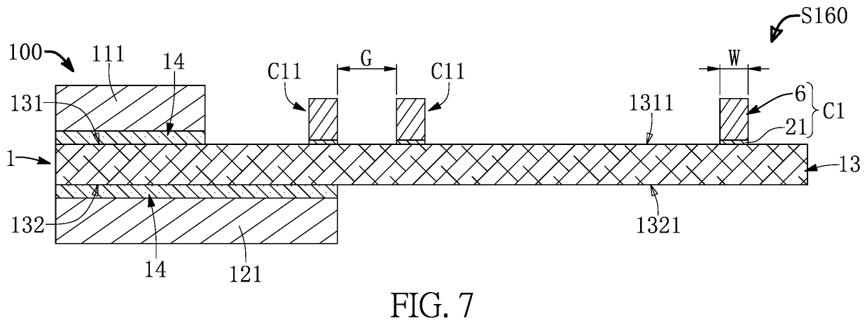

As shown in FIG. 1, FIG. 6, and FIG. 7, the chemical etching step S160 is implemented by removing the first shielding layer 4 and another part of the first sputtering conductor layer 2 connected to (or shielded by) the first shielding layer 2, so as to preserve the first electroplating layer 6 and the first sputtering layout segment 21 that are jointly defined as a first thin circuit layer C1. Moreover, a thickness of the first thin circuit layer C1 is within a range from 1 μm to 150 μm, and a thickness of the first sputtering layout segment 21 is within a range from 0.1 μm to 1 μm. Furthermore, the chemical etching step S160 in the present embodiment is also implemented to remove the second shielding layer 5 and the second sputtering conductor layer 3, so that the second processing region 1321 is exposed in an external space.

In summary, the manufacturing method S100 provided by the present embodiment only has a slight lateral etching on the first sputtering layout segment 21 in the chemical etching step S160, so that the pattern accuracy of the first thin circuit layer C1 is not affected for preventing an electrical short from occurring at the first thin circuit layer C1. Accordingly, the first thick circuit layer 111 and the first thin circuit layer C1 can be accurately formed by implementing the above steps S110-S160 for meeting various requirements.

Specifically, the first thin circuit layer C1 in the present embodiment has a plurality of circuits C11. After the shielding step S140 (shown in FIG. 5), the electroplating step S150 (shown in FIG. 6), and the chemical etching step S160 (shown in FIG. 7) are performed, a distance G between any two of the circuits C11 adjacent to each other or a width W of any one of the circuits C11 has a lowest critical value (or a minimum value) being within a range from 30 μm to 60 μm. In other words, the lowest critical value of any one of the distance G and the width W in the first thin circuit layer C1 can be accurately maintained to be within a range from 30 μm to 60 μm according to design requirements, but the present disclosure is not limited thereto.

The above description describes the manufacturing method S100 provided by the present embodiment, and the following description substantially describes the circuit board structure 100 produced by implementing the manufacturing method S100. Accordingly, some features of the circuit board structure 100 can be referred to in the above description of the manufacturing method S100 for the sake of brevity, but the present disclosure is not limited thereto.

The circuit board structure 100 in the present embodiment includes the ceramic board 13, the first thick circuit layer 111 formed on the first surface 131 of the ceramic board 13, the first thin circuit layer C1 formed on the first surface 131 of the ceramic board 13, and the second thick circuit layer 121 that is formed on the second surface 132 of the ceramic board 13. The thickness of the first thick circuit layer 111 and the thickness of the second thick circuit layer 121 are the same and each can be greater than or equal to 200 μm, but the present disclosure is not limited thereto.

In the present embodiment, the first thick circuit layer 111 and the second thick circuit layer 121 are respectively sintered and fixed onto the first surface 131 and the second surface 132 of the ceramic board 13 (through the two connection layers 14). Or, the first thick circuit layer 111 and the second thick circuit layer 121 are respectively brazed and fixed onto the first surface 131 and the second surface 132 of the ceramic board 13 (through the two connection layers 14).

Specifically, the first processing region 1311 of the first surface 131 is not covered by the first thick circuit layer 111 and is not connected to the corresponding connection layer 14, and the second processing region 1321 of the second surface 132 is not covered by the second thick circuit layer 121 and is not connected to the corresponding connection layer 14.

Moreover, the first thin circuit layer C1 is formed on the first processing region 1311 of the first surface 131 and is spaced apart from the first thick circuit layer 111, and the second processing region 1321 of the second surface 132 in the present embodiment is provided without any circuit formed thereon. The first thin circuit layer C1 has a plurality of circuits C11, and the distance G between any two of the circuits C11 adjacent to each other or the width W of any one of the circuits C11 can be formed to meet the lowest critical value being within a range from 30 μm to 60 μm.

Specifically, the first thin circuit layer C1 in the present embodiment includes the first sputtering layout segment 21 connected to the first surface 131 and the first electroplating layer 6 that is connected to the first sputtering layout segment 21, and the first electroplating layer 6 and the first sputtering layout segment 21 are respectively made of different materials. The thickness of the first thin circuit layer C1 is within a range from 1 μm to 150 μm, and the thickness of first sputtering layout segment 21 is within a range from 0.1 μm to 1 μm.

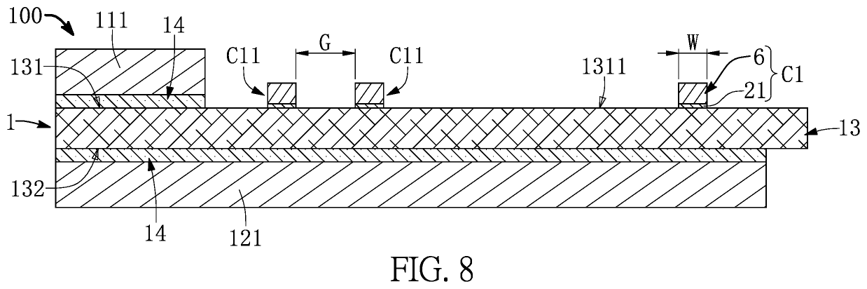

In addition, the above description of the circuit board structure 100 is described according to FIG. 7, but the circuit board structure 100 can be adjusted or changed according to design requirements. For example, as shown in FIG. 8 to FIG. 10, the second thick circuit layer 121 can be a structure that does not have any pattern, and the first thin circuit layer C1 is arranged on a projection region defined by orthogonally projecting the second thick circuit layer 121 onto the first surface 131.

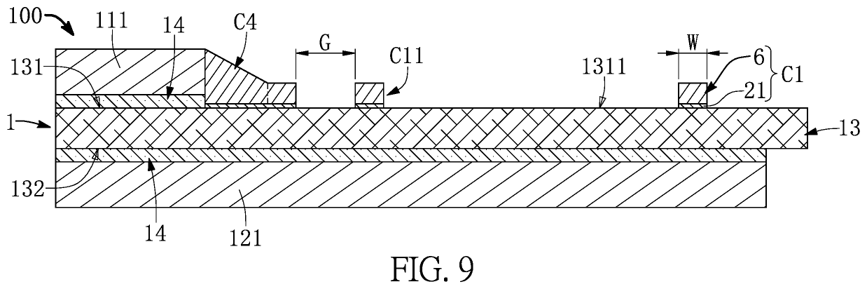

Moreover, as shown in FIG. 9, the circuit board structure 100 includes a lateral connection portion C4 formed on the first surface 131. The lateral connection portion C4 is connected in-between the first thick circuit layer 111 and the first thin circuit layer C1. Moreover, a thickness of the lateral connection portion C4 gradually decreases in a direction from the thick circuit layer 111 to the thin circuit layer C1. In other words, a cross section of the lateral connection portion C4 is substantially in the shape of a triangle.

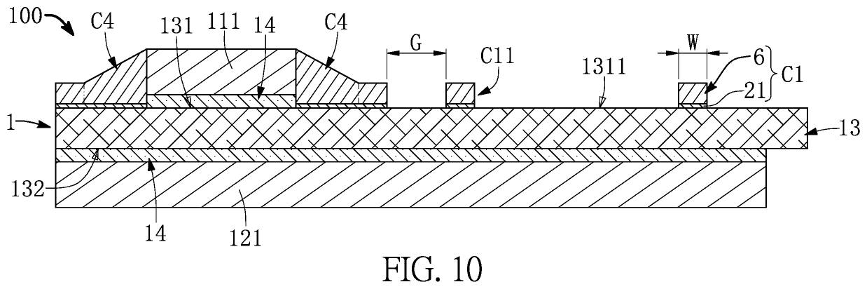

Or, as shown in FIG. 10, the circuit board structure 100 includes two lateral connection portions C4 formed on the first surface 131. Each of the two lateral connection portions C4 is connected in-between the first thick circuit layer 111 and the first thin circuit layer C1. In other words, the two lateral connection portions C4 are respectively connected to two opposite sides of the first thick circuit layer 111, and are respectively connected to two of the circuits C11 of the first thin circuit layer C1 that are arranged adjacent to the first thick circuit layer 111.

Moreover, a thickness of each of the two lateral connection portions C4 gradually decreases in a direction from the thick circuit layer 111 to the thin circuit layer C1. In other words, a cross section of each of the two lateral connection portions C4 is substantially a triangle, and a corresponding one of the two connection layers 14 is embedded in the two lateral connection portions C4 and the first thick circuit layer 111.

### Second Embodiment

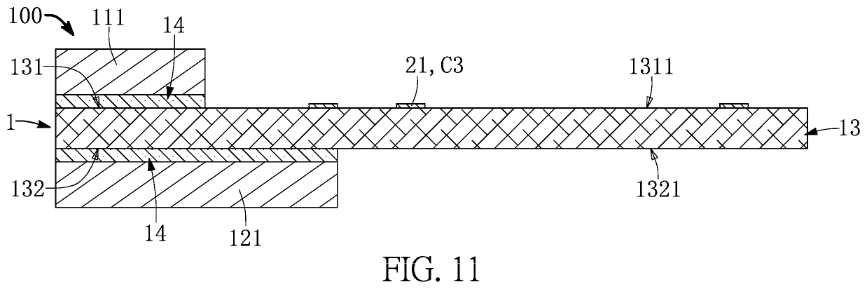

Referring to FIG. 11, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

In the present embodiment, the circuit board structure 100 is not formed with the first electroplating layer, and the first sputtering layout segment 21 is defined as a sputtering circuit layer C3. In other words, the sputtering circuit layer C3 of the circuit board structure 100 in the present embodiment is formed on the first processing region 1311 of the first surface 131, and a thickness of the sputtering circuit layer C3 is within a range from 0.1 μm to 1 μm.

### Third Embodiment

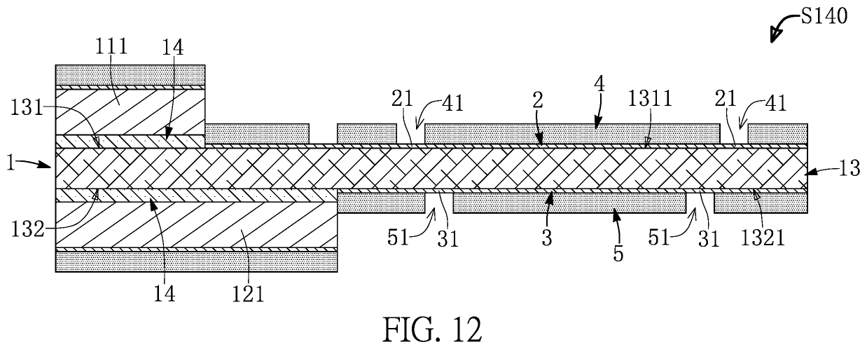

Referring to FIG. 12 to FIG. 14, a third embodiment of the present disclosure, which is similar to the first embodiment of the present disclosure, is provided. For the sake of brevity, descriptions of the same components in the first and third embodiments of the present disclosure (e.g., the preparing step, the patterning step, and the sputtering step) will be omitted herein, and the following description only discloses different features between the first and third embodiments.

As shown in FIG. 12, the shielding step S140 in the present embodiment is implemented by forming a first shielding layer 4 onto the first sputtering conductor layer 2 and by forming a second shielding layer 5 onto the second sputtering conductor layer 3. The first shielding layer 4 has a first patterned trench 41, and a part of the first sputtering conductor layer 2 is exposed from the first shielding layer 4 through the first patterned trench 41 and is defined as a first sputtering layout segment 21. Moreover, the second shielding layer 5 has a second patterned trench 51, and a part of the second sputtering conductor layer 3 is exposed from the second shielding layer 5 through the second patterned trench 51 and is defined as a second sputtering layout segment 31, but the present disclosure is not limited thereto.

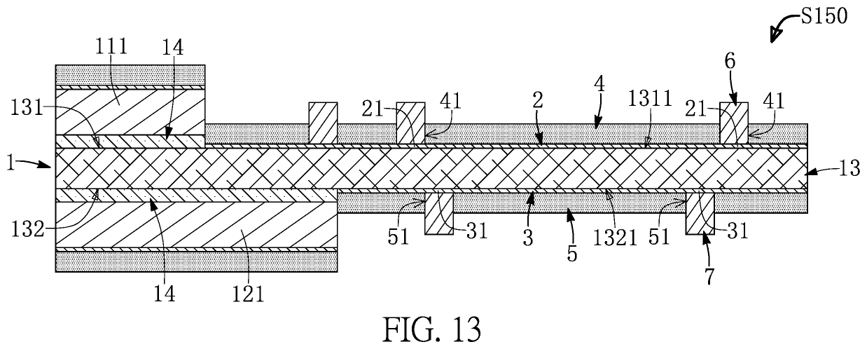

As shown in FIG. 12 and FIG. 13, the electroplating step S150 is implemented by electroplating the first sputtering layout segment 21 of the first sputtering conductor layer 2 and the second sputtering layout segment 31 of the second sputtering conductor layer 3 to respectively form a first electroplating layer 6 that is connected to the first sputtering layout segment 21 and a second electroplating layer 7 that is connected to the second sputtering layout segment 31. In the present embodiment, the first electroplating layer 6 and the second electroplating layer 7 are made of a same material that is different from a material of the first sputtering layout segment 21, but the present disclosure is not limited thereto.

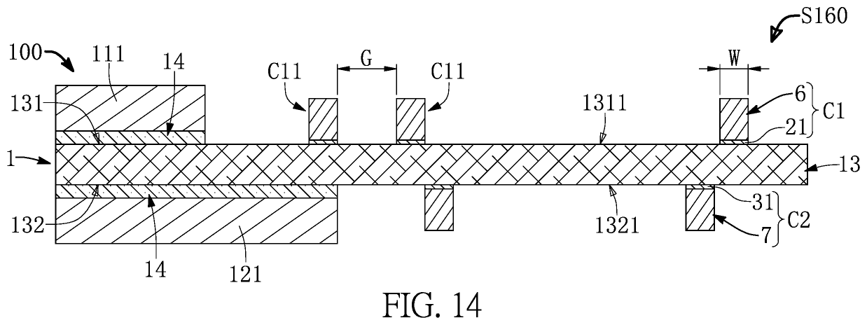

As shown in FIG. 13 and FIG. 14, the chemical etching step S160 is implemented by removing the first shielding layer 4 and another part of the first sputtering conductor layer 2 connected to (or shielded by) the first shielding layer 2, so as to preserve the first electroplating layer 6 and the first sputtering layout segment 21 that are jointly defined as a first thin circuit layer C1, and is further implemented by removing the second shielding layer 5 and another part of the second sputtering conductor layer 3 connected to (or shielded by) the second shielding layer 3, so as to preserve the second electroplating layer 7 and the second sputtering layout segment 31 that are jointly defined as a second thin circuit layer C2.

### Fourth Embodiment

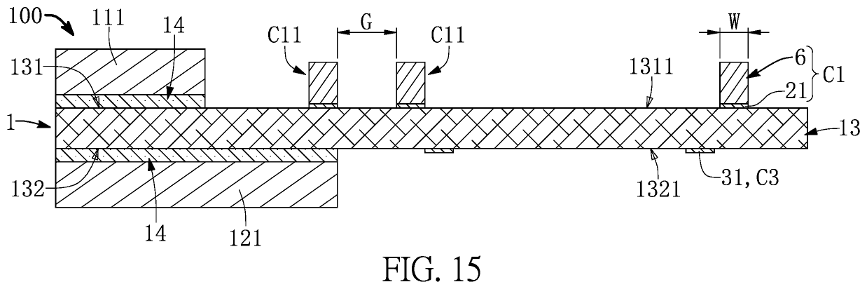

Referring to FIG. 15, a fourth embodiment of the present disclosure, which is similar to the third embodiment of the present disclosure, is provided. For the sake of brevity, descriptions of the same components in the third and fourth embodiments of the present disclosure will be omitted herein, and the following description only discloses different features between the third and fourth embodiments.

In the present embodiment, the circuit board structure 100 is formed without the second electroplating layer, and the second sputtering layout segment 31 is defined as a sputtering circuit layer C3. In other words, the sputtering circuit layer C3 of the circuit board structure 100 in the present embodiment is formed on the second processing region 1321 of the second surface 132, and a thickness of the sputtering circuit layer C3 is within a range from 0.1 μm to 1 μm.

Accordingly, the circuit board structure 100 in the present embodiment can be provided with three kinds of metal circuits (e.g., the first thick circuit layer 111 formed in a sintered manner or a brazed manner, the first thin circuit layer C1 formed in a sputtering and electroplating manner, and the sputtering circuit layer C3 formed in a sputtering manner), thereby meeting various practical requirements.

### BENEFICIAL EFFECTS OF THE EMBODIMENTS

In conclusion, any one of the manufacturing method and the circuit board structure provided by the present disclosure only has a slightly lateral etching on the first sputtering layout segment (or the sputtering circuit layer) through the steps and configuration thereof, so that the pattern accuracy of the first thin circuit layer (or the sputtering circuit layer) is not affected for preventing the first thin circuit layer (or the sputtering circuit layer) from generating an electrical short issue. Accordingly, the first thick circuit layer and the first thin circuit layer (or the sputtering circuit layer) can be accurately formed by implementing the above steps for meeting various requirements.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A manufacturing method of a circuit board structure, comprising:
a preparing step implemented by providing a metallized ceramic substrate, wherein the metallized ceramic substrate includes:
a ceramic board having a first surface and a second surface that is opposite to the first surface; and
a first metal layer and a second metal layer respectively formed on the first surface and the second surface of the ceramic board;
a patterning step implemented by patterning the first metal layer to remove a part of the first metal layer so as to form a first thick circuit layer, wherein a thickness of the first thick circuit layer is greater than or equal to 200 μm, and a part of the first surface is exposed from the first thick circuit layer and is defined as a first processing region;
a sputtering step implemented by sputtering the first processing region of the ceramic board to form a first sputtering conductor layer;
a shielding step implemented by forming a first shielding layer onto the first sputtering conductor layer, wherein the first shielding layer has a first patterned trench, and a part of the first sputtering conductor layer is exposed from the first shielding layer through the first patterned trench and is defined as a first sputtering layout segment;
an electroplating step implemented by electroplating the first sputtering layout segment of the first sputtering conductor layer to form a first electroplating layer that is connected to the first sputtering layout segment; and
a chemical etching step implemented by removing the first shielding layer and another part of the first sputtering conductor layer connected to the first shielding layer so as to preserve the first electroplating layer and the first sputtering layout segment that are jointly defined as a first thin circuit layer, wherein a thickness of the first thin circuit layer is within a range from 1 μm to 150 μm.

2. The manufacturing method according to claim 1, wherein the first thin circuit layer has a plurality of circuits, and after the shielding step, the electroplating step, and the chemical etching step are performed, a distance between any two of the circuits adjacent to each other or a width of any one of the circuits has a lowest critical value being within a range from 30 μm to 60 μm.

3. The manufacturing method according to claim 1, wherein a thickness of the first sputtering layout segment is within a range from 0.1 μm to 1 μm, and wherein material of the first electroplating layer is different from material of the first sputtering layout segment, such that the first electroplating layer in the chemical etching step has no lateral etching.

4. The manufacturing method according to claim 1, wherein, in the patterning step, the second metal layer is patterned by removing a part thereof so as to form a second thick circuit layer having a thickness being greater than or equal to 200 μm.

5. The manufacturing method according to claim 4, wherein, in the patterning step, a part of the second surface is exposed from the second thick circuit layer and is defined as a second processing region, wherein, in the sputtering step, the second processing region is sputtered to from a second sputtering conductor layer, and wherein, in the shielding step, a second shielding layer is formed on the second sputtering conductor layer.

6. The manufacturing method according to claim 5, wherein, in the chemical etching step, the second shielding layer and the second sputtering conductor layer are removed, and the second processing region is exposed in an external space.

7. The manufacturing method according to claim 5, wherein, in the shielding step, the second shielding layer has a second patterned trench, and a part of the second sputtering conductor layer is exposed from the second shielding layer through the second patterned trench and is defined as a second sputtering layout segment, wherein, in the electroplating step, the second sputtering layout segment is electroplated to form a second electroplating layer that is connected thereto, and wherein, in the chemical etching step, the second shielding layer and another part of the second sputtering conductor layer connected to the second shielding layer are removed so as to preserve the second electroplating layer and the second sputtering layout segment that are jointly defined as a second thin circuit layer.

8. The manufacturing method according to claim 1, wherein, in the preparing step, the metallized ceramic substrate is a direct bonded copper (DBC) ceramic substrate, and the first metal layer and the second metal layer are respectively sintered onto the first surface and the second surface of the ceramic board.

9. The manufacturing method according to claim 1, wherein, in the preparing step, the metallized ceramic substrate is an active metal brazing (AMB) ceramic substrate, and the first metal layer and the second metal layer are respectively brazed onto the first surface and the second surface of the ceramic board.

10. A circuit board structure, comprising:
a ceramic board having a first surface and a second surface that is opposite to the first surface;
a thick circuit layer formed on the first surface of the ceramic board and having a thickness that is greater than or equal to 200 μm, wherein a part of the first surface is exposed from the first thick circuit layer and is defined as a first processing region; and
a thin circuit layer formed on the first processing region of the first surface and having a thickness that is within a range from 1 μm to 150 μm;
wherein the thin circuit layer includes a sputtering layout segment connected to the first surface and a first electroplating layer that is connected to the sputtering layout segment, and the first electroplating layer and the first sputtering layout segment are respectively made of different materials.

11. The circuit board structure according to claim 10, wherein the first thick circuit layer and the first thin circuit layer are spaced apart from each other.

12. The circuit board structure according to claim 10, further comprising at least one lateral connection portion formed on the first surface, wherein the at least one lateral connection portion is connected in-between the first thick circuit layer and the first thin circuit layer.

13. The circuit board structure according to claim 12, wherein a thickness of the at least one lateral connection portion gradually decreases in a direction from the thick circuit layer to the thin circuit layer.

14. The circuit board structure according to claim 10, further comprising a second thick circuit layer formed on the second surface of the ceramic board, wherein a thickness of the second thick circuit layer is greater than or equal to 200 μm.

15. The circuit board structure according to claim 14, wherein a part of the second surface is exposed from the second thick circuit layer and is defined as a second processing region, and wherein the circuit board structure further includes a second sputtering conductor layer that is formed on the second processing region and that has a thickness being within a range from 0.1 μm to 1 μm.

16. The circuit board structure according to claim 14, wherein the first thick circuit layer and the second thick circuit layer are respectively sintered onto the first surface and the second surface of the ceramic board.

17. The circuit board structure according to claim 14, wherein the first thick circuit layer and the second thick circuit layer are respectively brazed onto the first surface and the second surface of the ceramic board.

18. The circuit board structure according to claim 14, wherein the first thin circuit layer is arranged on a projection region defined by orthogonally projecting the second thick circuit layer onto the first surface.

19. The circuit board structure according to claim 10, wherein the first thin circuit layer has a plurality of circuits, and a distance between any two of the circuits adjacent to each other or a width of any one of the circuits has a lowest critical value being within a range from 30 μm to 60 μm.

20. A circuit board structure, comprising:
a ceramic board having a first surface and a second surface that is opposite to the first surface;
a thick circuit layer formed on the first surface of the ceramic board and having a thickness that is greater than or equal to 200 μm, wherein a part of the first surface is exposed from the first thick circuit layer and is defined as a first processing region; and
a sputtering circuit layer formed on the first processing region of the first surface and having a thickness that is within a range from 0.1 μm to 1 μm.
